(19) United States
(12) Patent Application Publication
(10) Pub. No.: US 2026/0362753 A1
(43) Pub. Date: Nov. 12, 2026

(54) GATE OXIDE STACKS FOR SILICON CARBIDE MOSFETS

(71) Applicant: Microchip Technology Incorporated, Chandler, AZ (US)

(72) Inventor: Yogesh Sharma, Colorado Springs, CO (US)

(73) Assignee: Microchip Technology Incorporated, Chandler, AZ (US)

(21) Appl. No.: 19/273,370

(22) Filed: Jul. 18, 2025

Related U.S. Application Data
(60) Provisional application No. 63/803,292, filed on May 9, 2025.

(51) Int. Cl. H10D 30/69; H10D 30/01; H10D 30/66; H10D 62/832; H10D 64/27; H10D 64/68

(52) U.S. Cl. CPC H10D 30/792; H10D 30/0291; H10D 30/66; H10D 64/514; H10D 64/683; H10D 64/691; H10D 64/693; H10D 62/8325

(57) ABSTRACT

Technologies for gate oxide stacks for silicon carbide metal-oxide-semiconductor field-effect transistors (MOSFET) are disclosed. In one example, a silicon carbide high-voltage power MOSFET includes a gate dielectric stack of two or more layers. In one example, the gate dielectric stack includes a silicon oxide layer adjacent the silicon carbide die and a silicon nitride layer above the silicon oxide layer. A gate electrode may be above the silicon nitride layer. The silicon nitride layer may impact a stress between the silicon oxide layer and a channel region of the transistor, increasing electron mobility in the channel region.

### CROSS-REFERENCE TO RELATED APPLICATION

This application claims the benefit under 35 U.S.C. § 119(e) of U.S. Provisional Patent Application Ser. No. 63/803,292, filed May 9, 2025, entitled “GATE OXIDE STACKS FOR SILICON CARBIDE MOSFETS,” the entirety of which application is incorporated by reference herein.

### TECHNICAL FIELD

The present disclosure relates generally to silicon carbide metal-oxide-semiconductor field effect transistors (MOSFET), and more specifically to gate oxide stacks for improved electron mobility in the channel of silicon carbide MOSFETs.

### BACKGROUND

Silicon carbide transistors often have a silicon oxide gate. Defects at the interface between the silicon carbide substrate and the silicon oxide gate can reduce the electron mobility of the channel region of the transistor. Reducing the defects, such as by annealing under, e.g., nitric oxide, can increase the electron mobility of the channel region.

### SUMMARY OF THE INVENTION

Aspects of various examples include silicon carbide transistors with a gate dielectric stack including an oxide layer, such as silicon oxide, and a nitride layer, such as nitrogen oxide. The nitrogen oxide layer can improve electron mobility in the channel under the interface of the silicon oxide and the silicon carbide.

### BRIEF DESCRIPTION OF THE DRAWINGS

FIG. 1 is a simplified drawing of one example of a silicon carbide transistor.

FIG. 2 is a flowchart of one example of a method of creating one example of the silicon carbide transistor of FIG. 1.

FIG. 3 is a simplified drawing of one stage of the transistor for one example of the flowchart of FIG. 2.

FIG. 4 is a simplified drawing of one stage of the transistor for one example of the flowchart of FIG. 2.

FIG. 5 is a simplified drawing of one stage of the transistor for one example of the flowchart of FIG. 2.

FIG. 6 is a simplified drawing of one stage of the transistor for one example of the flowchart of FIG. 2.

FIG. 7 is a simplified drawing of one stage of the transistor for one example of the flowchart of FIG. 2.

FIG. 8 is a simplified drawing of one stage of the transistor for one example of the flowchart of FIG. 2.

FIG. 9 is a simplified drawing of one stage of the transistor for one example of the flowchart of FIG. 2.

FIG. 10 is a simplified drawing of one stage of the transistor for one example of the flowchart of FIG. 2.

FIG. 11 is a simplified drawing of one stage of the transistor for one example of the flowchart of FIG. 2.

FIG. 12 is a simplified drawing of one stage of the transistor for one example of the flowchart of FIG. 2.

FIG. 13 is a simplified drawing of one stage of the transistor for one example of the flowchart of FIG. 2.

FIG. 14 is a simplified drawing of one stage of the transistor for one example of the flowchart of FIG. 2.

FIG. 15 is a simplified drawing of one stage of the transistor for one example of the flowchart of FIG. 2.

FIG. 16 illustrates an example integrated circuit device that may include one or more components in accordance with examples disclosed herein.

FIG. 17 is a simplified block diagram of at least one example of a compute device that may include the transistor of FIG. 1.

### DETAILED DESCRIPTION

The approach disclosed herein addresses electron mobility in silicon carbide transistors. In one example, a gate dielectric stack for a silicon carbide transistor includes a silicon oxide layer next to the top surface of the silicon carbide die and a silicon nitride layer on top of the silicon oxide layer. The silicon nitride layer impacts the stress between the silicon oxide layer and the channel region of the transistor, increasing the electron mobility in the channel region.

In the following description, specific details are set forth, but examples of the technologies described herein may be practiced without these specific details. Well-known circuits, structures, and techniques have not been shown in detail to avoid obscuring an understanding of this description. Phrases such as “an example,” “various examples,” “some examples,” and the like may include features, structures, or characteristics, but not every example necessarily includes the particular features, structures, or characteristics.

Some examples may have some, all, or none of the features described for other examples. “First,” “second,” “third,” and the like describe a common object and indicate different instances of like objects being referred to. Such adjectives do not imply objects so described must be in a given sequence, either temporally or spatially, in ranking, or any other manner. “Connected” may indicate elements are in direct physical or electrical contact with each other and “coupled” may indicate elements cooperate or interact with each other, but they may or may not be in direct physical or electrical contact. Furthermore, the terms “comprising,” “including,” “having,” and the like, as used with respect to examples of the present disclosure, are synonymous.

As used herein, the phrase “located on” in the context of a first layer or component located on a second layer or component refers to the first layer or component being directly physically attached to the second part or component (no layers or components between the first and second layers or components) or physically attached to the second layer or component with one or more intervening layers or components. As used herein, the term “adjacent” refers to layers or components that are in physical contact with each other. That is, there is no layer or component between the stated adjacent layers or components. For example, a layer X that is adjacent to a layer Y refers to a layer that is in physical contact with layer Y. As used herein, a die may be considered to be adjacent a substrate if there are no layers or components between the die and the substrate, although there can be, without limitation, pads or solder balls between the substrate and the die, with the die and the substrate still considered to be adjacent. As used herein, the phrase “electrically coupled” refers to the presence of one or more electrically conductive paths between components that are recited as being electrically coupled.

Certain terminology may also be used herein for the purpose of reference only, and thus are not intended to be limiting. For example, terms such as “upper,” “lower,” “above,” “below,” “bottom,” and “top” refer to directions in the Figures to which reference is made. Terms such as “front,” “back,” “rear,” and “side” describe the orientation, location, or both orientation and location of, without limitation, layers, components or portions of components, within a consistent but arbitrary frame of reference, which is made clear by reference to the text and the associated Figures describing the, without limitation, layers, component or portions of components under discussion. Such terminology may include the words specifically mentioned above, derivatives thereof, and words of similar import.

As used herein, the term “integrated circuit component” refers to a packaged or unpacked integrated circuit product. A packaged integrated circuit component comprises one or more integrated circuit dies mounted on a package substrate with the integrated circuit dies and package substrate encapsulated in a casing material, such as metal, plastic, glass, or ceramic. In one example, a packaged integrated circuit component contains one or more processor units mounted on a substrate with an exterior surface of the substrate comprising a solder ball grid array (BGA). In one example of an unpackaged integrated circuit component, a single monolithic integrated circuit die comprises solder bumps attached to contacts on the die. The solder bumps allow the die to be directly attached to a printed circuit board. An integrated circuit component can comprise one or more of any computing system component described or referenced herein or any other computing system component, such as a processor unit (e.g., system-on-a-chip (SoC), processor core, graphics processor unit (GPU), accelerator, chipset processor), I/O controller, memory, or network interface controller.

As used herein, the term “electronic component” can refer to an active electronic component (e.g., processing unit, memory, storage device, transistor) or a passive electronic component (e.g., resistor, inductor, capacitor).

As used herein, the terms “operating,” “executing,” or “running” as they pertain to software or firmware in relation to a system, device, platform, or resource are used interchangeably and can refer to software or firmware stored in one or more computer-readable storage media accessible by the system, device, platform or resource, even though the software or firmware instructions are not actively being executed by the system, device, platform, or resource.

Reference is now made to the drawings, which are not necessarily drawn to scale, wherein similar or the same numbers may be used to designate the same or similar parts in different figures. The use of similar or the same numbers in different figures does not mean all figures including similar or the same numbers constitute a single or same example. Like numerals having different letter suffixes may represent different instances of similar components. The drawings illustrate generally, by way of example, but not by way of limitation, various examples discussed in the present document.

In the following description, for purposes of explanation, numerous specific details are set forth in order to provide a thorough understanding thereof. It may be evident, however, that the novel examples can be practiced without these specific details. In other instances, well-known structures and devices are shown in block diagram form in order to facilitate a description thereof. The intention is to cover all modifications, equivalents, and alternatives within the scope of the claims.

As used in this application and the claims, a list of items joined by the term “and/or” can mean any combination of the listed items. For example, the phrase “A, B, and/or C” can mean A; B; C; A and B; A and C; B and C; or A, B and C. As used in this application and the claims, a list of items joined by the term “at least one of” can mean any combination of the listed terms. For example, the phrase “at least one of A, B, or C” can mean A; B; C; A and B; A and C; B and C; or A, B, and C. Moreover, as used in this application and the claims, a list of items joined by the term “one or more of” can mean any combination of the listed terms. For example, the phrase “one or more of A, B, and C” can mean A; B; C; A and B; A and C; B and C; or A, B, and C.

As used in this application and the claims, the phrase “individual of” or “respective of” followed by a list of items recited or stated as having a, without limitation, trait or feature means that all of the items in the list possess the stated or recited trait or feature. For example, the phrase “individual of A, B, or C, comprise a sidewall” or “respective of A, B, or C, comprise a sidewall” means that A comprises a sidewall, B comprises a sidewall, and C comprises a sidewall.

The disclosed methods, apparatuses, and systems are not to be construed as limiting in any way. Instead, the present disclosure is directed toward all novel and nonobvious features and aspects of the various disclosed examples, alone and in various combinations and subcombinations with one another. The disclosed methods, apparatuses, and systems are not limited to any specific aspect or feature or combination thereof, nor do the disclosed examples require that any one or more specific advantages be present or problems be solved.

Theories of operation, scientific principles, or other theoretical descriptions presented herein in reference to the apparatuses or methods of this disclosure have been provided for the purposes of better understanding and are not intended to be limiting in scope. The apparatuses and methods in the appended claims are not limited to those apparatuses and methods that function in the manner described by such theories of operation.

Although the operations of some of the disclosed methods are described in a particular, sequential order for convenient presentation, it is to be understood that this manner of description encompasses rearrangement, unless a particular ordering is required by specific language set forth herein. For example, operations described sequentially may in some cases be rearranged or performed concurrently. Moreover, for the sake of simplicity, the attached figures may not show the various ways in which the disclosed methods can be used in conjunction with other methods.

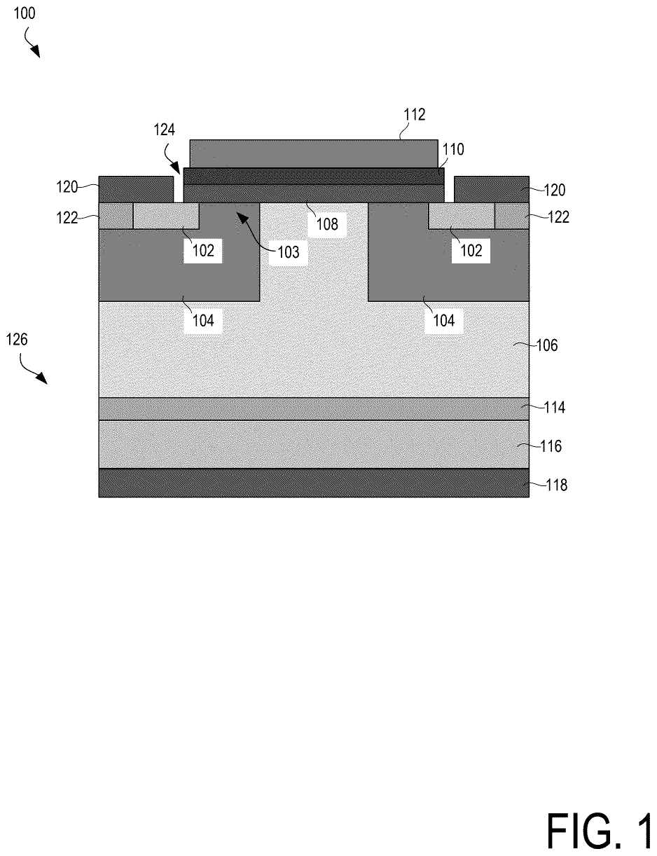

Referring now to FIG. 1, in various examples, a silicon carbide die 126 includes a high-voltage power silicon carbide transistor 100, which includes a source region 102, a channel region 103 in a p-well region 104, a drift region 106, a gate dielectric stack 124, a gate electrode 112, a buffer layer 114, a substrate 116 (or drain region), a drain contact 118, a source contact 120, and a body contact region 122. In various examples, the gate dielectric stack 124 includes a silicon oxide layer 108 and a silicon nitride layer 110. The silicon nitride layer 110 impacts the stress between the silicon oxide layer 108 and the channel region 103, increasing the electron mobility in the channel region 103. The silicon nitride layer 110 may increase the electron mobility of the channel region 103 to be above, e.g., 30 cm²/V⋅s, such as 50-100 cm²/V⋅s.

The high-voltage power silicon carbide transistor 100 may be able to operate at any suitable voltage, such as 2-3,000 volts (i.e., the high-voltage power silicon carbide transistor 100 may be able to maintain a voltage of 2-3,000 volts between the source contact 120 and the drain contact 118 when the transistor 100 is in the off state). In one example, the high-voltage power silicon carbide transistor 100 can operate up to 1,200 volts. The die 126 may have any suitable thickness, such as 50-500 micrometers. The gate dielectric stack 124 may have any suitable thickness, such as 10-200 nanometers. The silicon oxide layer 108 may have any suitable thickness, such as 5-100 nanometers, and the silicon nitride layer 110 may have any suitable thickness, such as 5-100 nanometers. In one example, the silicon oxide layer 108 has a thickness of about 50 nanometers (e.g., 45-55 nanometers) and the silicon nitride layer 110 has a thickness of, e.g., 10-15 nanometers. In some examples, the layer 110 above the silicon oxide layer 108 may be a different material, such as boron nitride.

In various examples, the channel region 103 and p-well region 104 may be a p-doped region, and the source region 102 and drift region 106 may be n-doped regions. In an one example, the body contact region 122 is heavily p-doped (e.g., 10¹⁹-10²⁰ dopants per cm³), the source region 102 is heaving n-doped (e.g., 10¹⁹-5×10²⁰ dopants per cm³), the p-well region 104 is lightly p-doped (e.g., 10¹⁷-5×10¹⁷ dopants per cm³), the drift region 106 is lightly n-doped (e.g., 10¹⁴-5×10¹⁵ dopants per cm³), the substrate 116 (or drain region) is heavily n-doped (e.g., 10¹⁸-5×10¹⁸ dopants per cm³), and the buffer layer 114 is n-doped between that of the drift region 106 and the substrate 116. In another example, the n and p doping may be reversed, with the well region 104 being n-doped, and so on. In various examples, any suitable n dopant may be used, such as nitrogen or phosphorous, and any suitable p dopant may be used, such as aluminum, boron, or gallium.

In one example, the gate electrode 112 is polysilicon. In other examples, the gate electrode 112 may be made of a different conductive material. The source contact 120, the drain contact 118, or both may be made of or otherwise include, e.g., nickel, titanium, tungsten, aluminum, or the like.

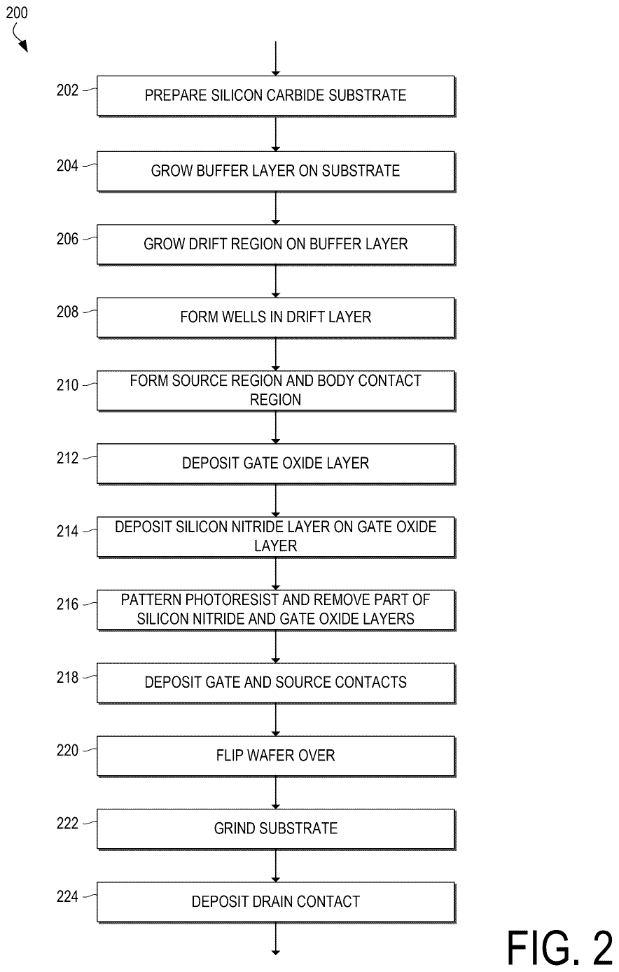

Referring now to FIG. 2, in one example, a flowchart for a method 200 for creating a transistor 100 is shown. The method 200 may be executed by a technician or by one or more automated machines or both. In some examples, one or more machines may be programmed to do some or all of the steps of the method 200. Such a machine may include, e.g., a memory, a processor, data storage, and so on. The memory or data storage or both may store instructions that, when executed by the machine, cause the machine to perform some or all of the steps of the method 200. The method 200 may use any suitable set of techniques that are used in semiconductor processing or circuit board processing, such as chemical vapor deposition, atomic layer deposition, physical layer deposition, molecular beam epitaxy, layer transfer, photolithography, ion implantation, dry etching, wet etching, selective laser etching, thermal treatments, flip chip, layer transfer, magnetron sputter deposition, pulsed laser deposition, laser machining, laser-induced deep etching, 3D photolithography, screen printing, ink jet printing, and so on. It should be appreciated that the method 200 is merely one example of a method to create one example of a system, and other methods may be used to create any suitable example of the system. In some examples, steps of the method 200 may be performed in a different order than that shown in the flowchart.

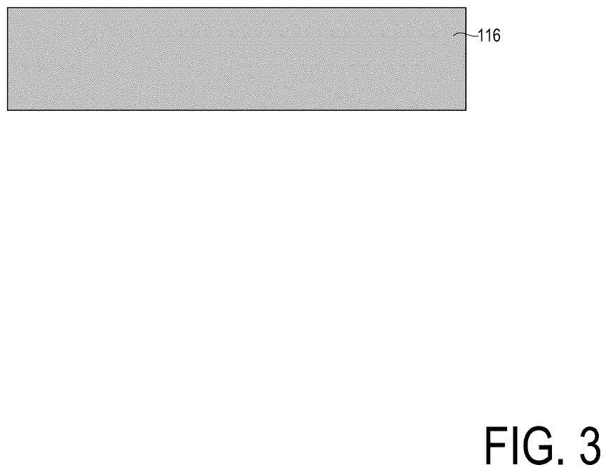

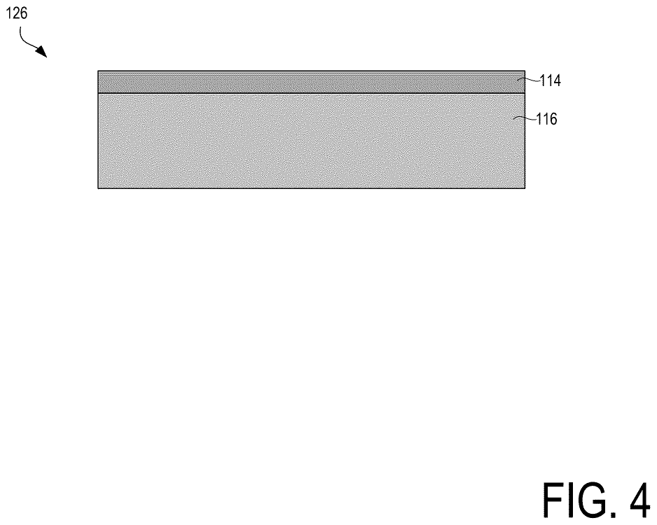

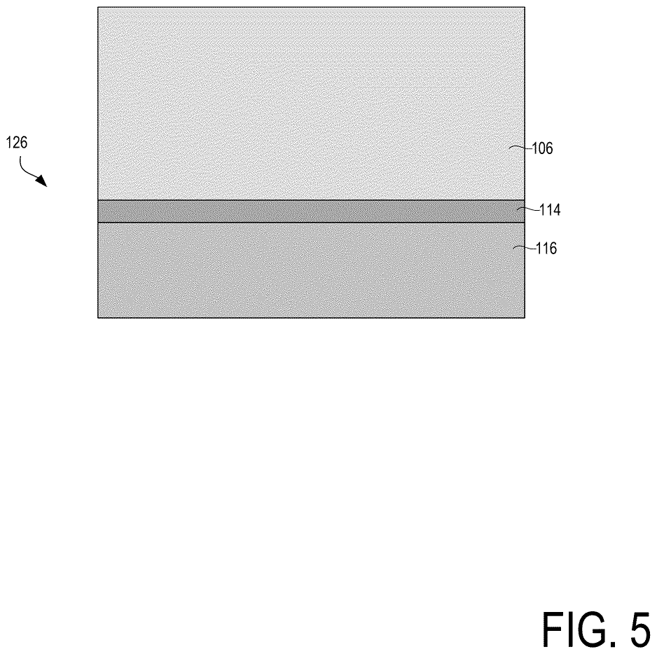

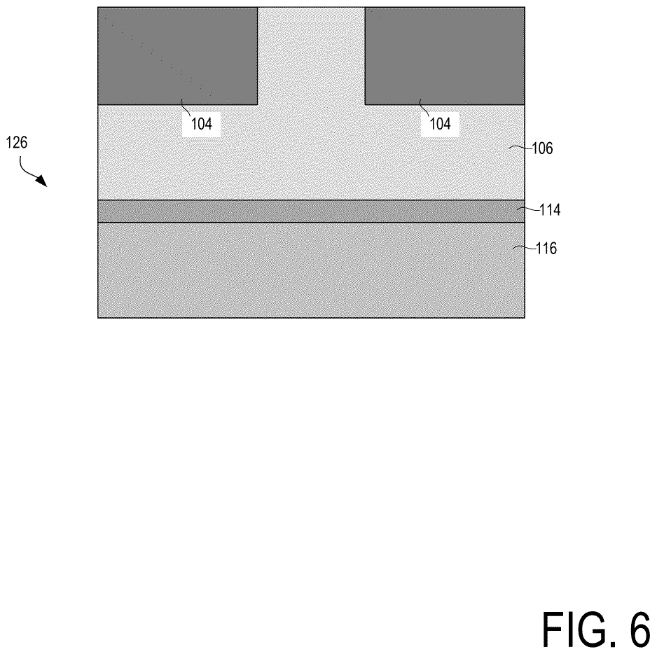

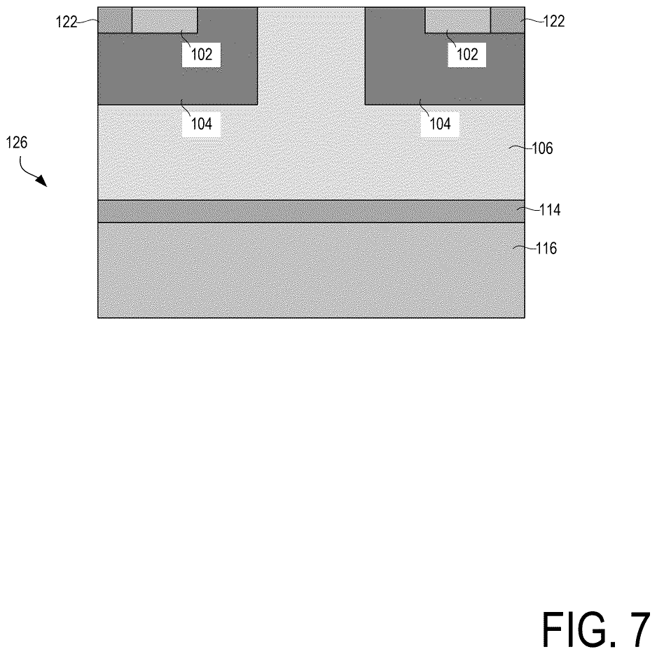

The method 200 begins in block 202, in which a silicon carbide substrate 116 is prepared, as shown in FIG. 3. In block 204, a buffer layer 114 of silicon carbide is epitaxially grown on the substrate 116, as shown in FIG. 4. In block 206, a drift region 106 of silicon carbide is epitaxially grown on the buffer layer 114, as shown in FIG. 5. In block 208, a p-well region 104 is formed in the drift region 106 by diffusion or ion implantation, as shown in FIG. 6. A source region 102 and body contact region 122 is formed in the p-well region 104 by diffusion or ion implantation in block 210, as shown in FIG. 7.

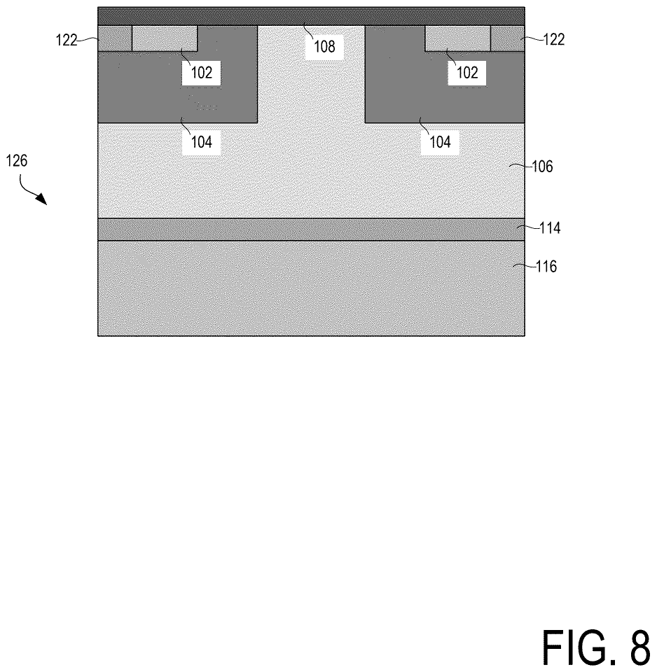

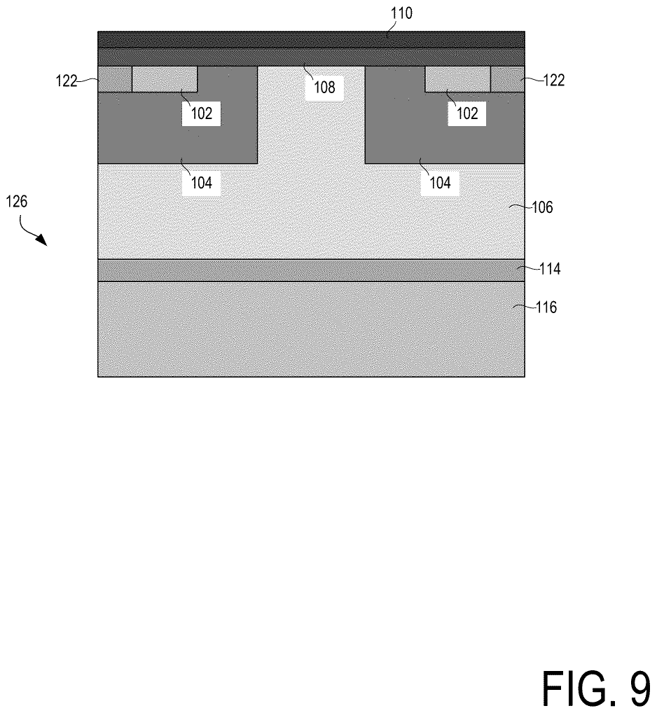

In block 212, a gate oxide layer 108 is deposited, as shown in FIG. 8. The gate oxide layer 108 may be annealed by flowing nitric oxide or nitrous oxide over the gate oxide layer 108 at a high temperature. The nitrogen may diffuse through the gate oxide layer 108 and bond with carbon in the well region 104. In block 214, a silicon nitride layer 110 is deposited on the gate oxide layer 108, as shown in FIG. 9.

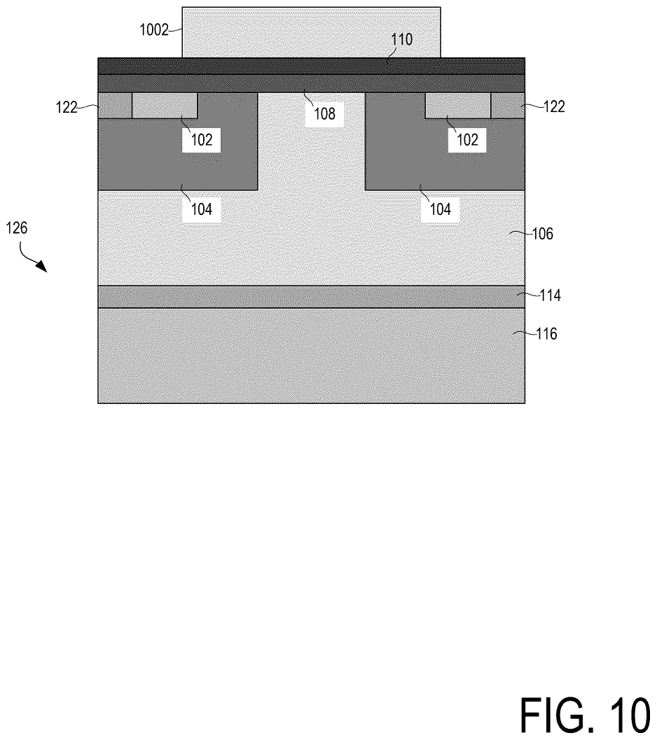

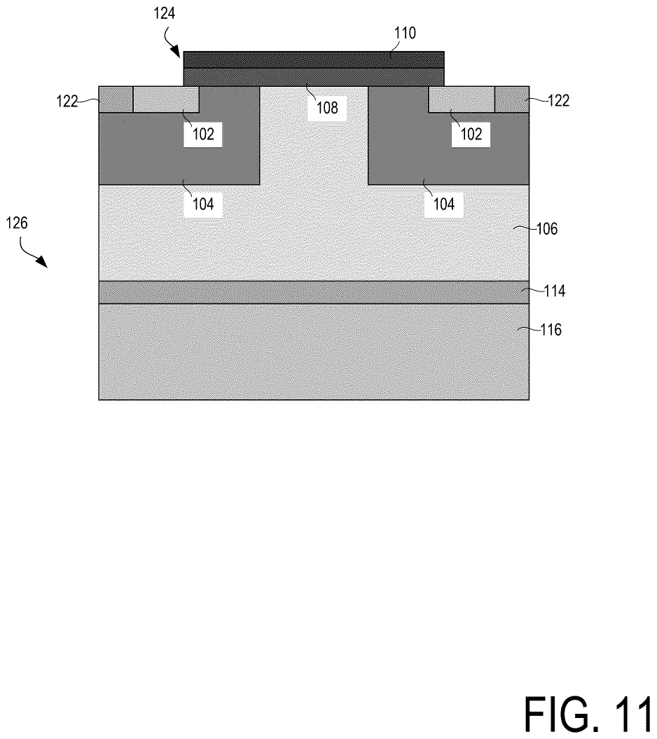

In block 216, a photoresist 1002 is patterned on the silicon oxide layer 108 and the silicon nitride layer 110, as shown in FIG. 10. It should be appreciated that the same mask can be used to pattern both the gate oxide layer 108 and the silicon nitride layer 110, simplifying the process. The excess gate oxide layer 108 and silicon nitride layer 110 is then removed in areas not protected by the photoresist 1002, as shown in FIG. 11.

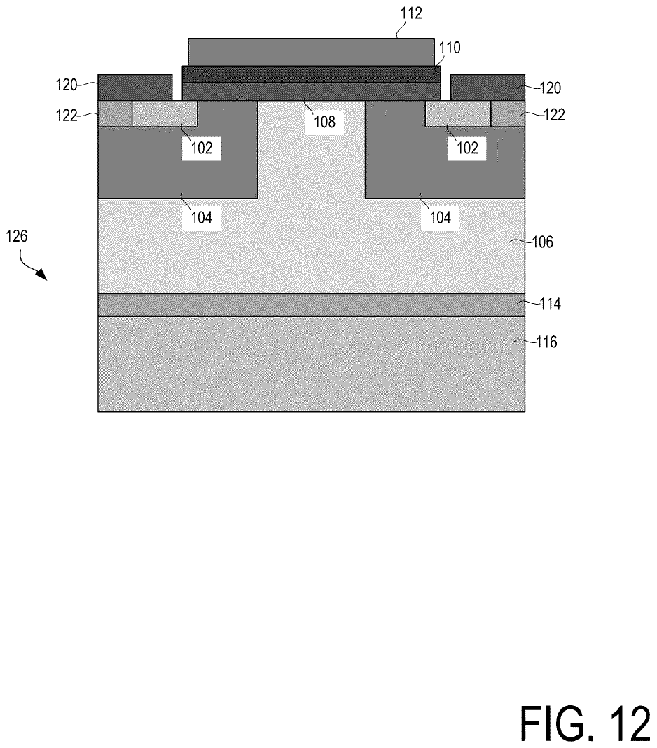

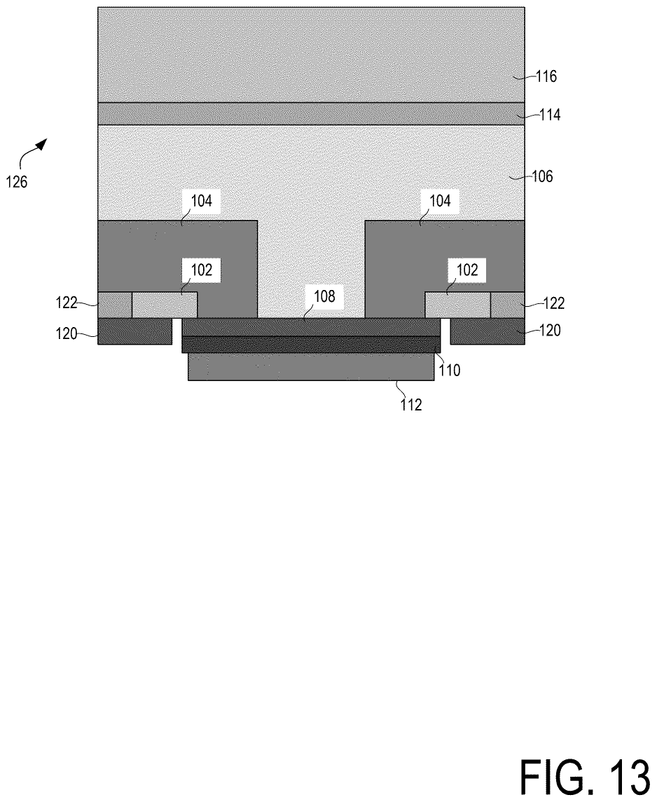

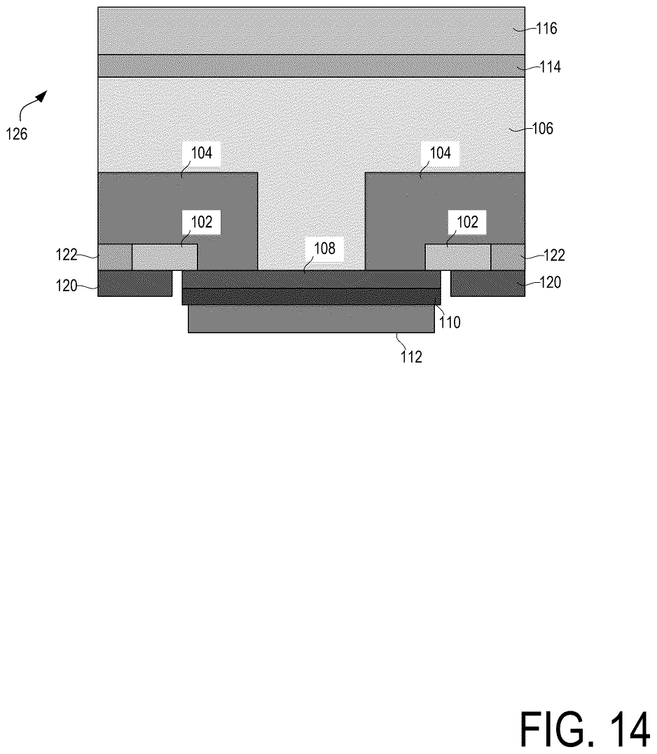

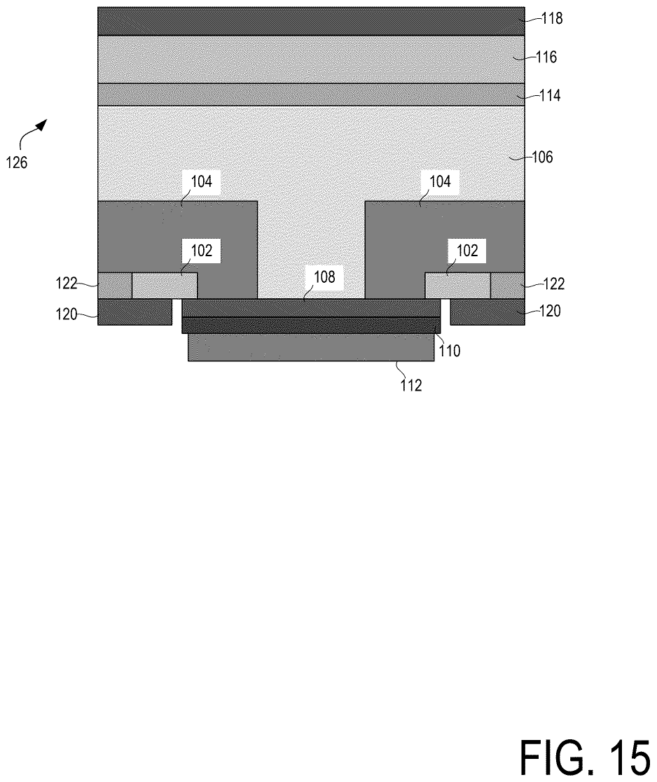

In block 218, the gate electrode 112 and source contacts 120 are formed, as shown in FIG. 12. In block 220, the wafer is flipped over, as shown in FIG. 13. The substrate 116 is then ground down to thin the substrate 116 in block 222, as shown in FIG. 14. The drain contact 118 is then deposited on the substrate 116 in block 224, as shown in FIG. 15.

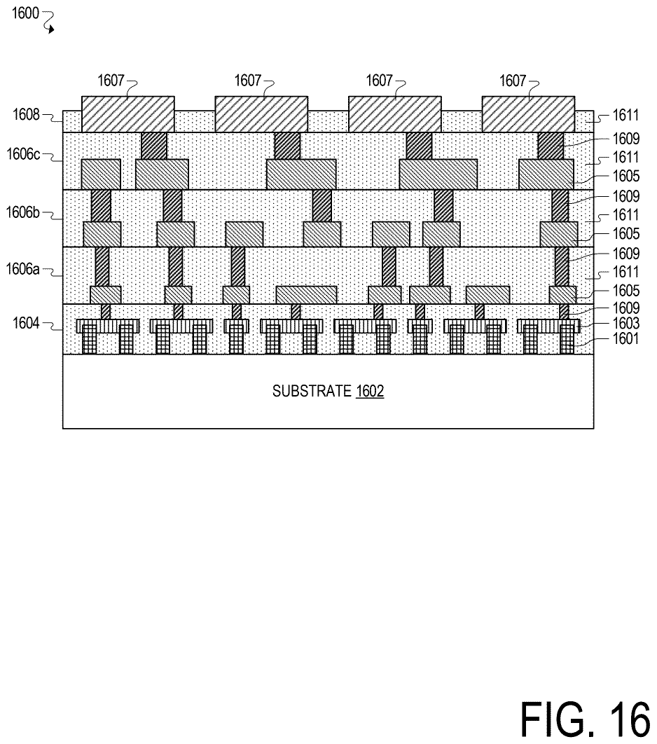

Referring now to FIG. 16, in one example, an integrated circuit (IC) device 1600 is shown. The IC device 1600 may include one or more high-voltage power silicon carbide transistors 100 in accordance with examples disclosed herein. In some examples, IC device 1600 may be included in an IC die, such as a system-on-chip (SoC) die, processor die, memory die, input/output (I/O) die, or power die (e.g., power management integrated circuit (PMIC)), among other examples.

In the illustrated example, IC device 1600 includes a semiconductor substrate 1602, a device layer 1604 over the semiconductor substrate 1602, multiple internal interconnect layers 1606a-c over the device layer 1604, and an external interconnect layer 1608 over the internal interconnect layers 1606a-c (e.g., on the upper surface of IC device 1600).

The semiconductor substrate 1602 may include any suitable semiconductor material, including, without limitation, silicon, silicon carbide, silicon germanium, germanium, indium antimonide, lead telluride, indium arsenide, indium phosphide, gallium arsenide, gallium antimonide, or other group II-VI, III-V, or IV semiconductor materials.

The device layer 1604 may include one or more semiconductor devices 1601 (e.g., transistors, diodes) formed in, on, or over the semiconductor substrate 1602. In some examples, the semiconductor devices 1601 may include, without limitation, bipolar junction transistors (BJTs), field-effect transistors (FETs), junction field-effect transistors (JFETs), metal-oxide-semiconductor field-effect transistors (MOSFETs), double-diffused metal-oxide-semiconductor (DMOS) transistors, laterally-diffused metal-oxide-semiconductor (LDMOS) transistors, complementary metal-oxide-semiconductor (CMOS) transistors (e.g., n-type MOS (NMOS) transistors, p-type MOS (PMOS) transistors), bipolar diodes (e.g., p-n junction diodes), unipolar diodes (e.g., metal-semiconductor junction (Schottky) diodes), bipolar-CMOS-DMOS (BCD) devices (e.g., integrated BJT, CMOS, and DMOS/LDMOS transistors on a single chip for mixed-signal (analog/digital) high-power applications), or combinations thereof.

In some examples, the semiconductor devices 1601 may include n-type semiconductor devices (e.g., NMOS transistors), p-type semiconductor devices (e.g., PMOS transistors), or a combination thereof.

The device layer 1604 also includes conductive contacts 1603 on the semiconductor devices 1601 (e.g., a source, drain, or gate contact 1603 coupled to the source, drain, or gate of a transistor 1601), which are electrically coupled to the internal interconnect layers 1606 by vias 1609.

The internal interconnect layers 1606a-c include conductive features 1605, such as traces or pads, embedded in dielectric material 1611 (e.g., dielectric buildup material such as Ajinomoto Build-Up Film (ABF)). The conductive features 1605 in different interconnect layers 1606a-c are electrically coupled to each other by vias 1609.

The external interconnect layer 1608 includes conductive contacts 1607 (e.g., pads) embedded in dielectric material 1611 (e.g., solder resist) on the upper surface of IC device 1600. The conductive contacts 1611 are electrically coupled to the internal interconnect layers 1606 by vias 1609. Moreover, the conductive contacts 1611 can be used to electrically couple IC device 1600 to another external IC device (not shown), such as an IC die, IC package, or circuit board (e.g., PCB).

The conductive features 1603, 1605, 1607 in different layers 1604, 1606a-c, 1608 of IC device 1600 are electrically coupled to each other by vias 1609. Moreover, all of the conductive features 1603, 1605, 1607, 1609 in IC device 1600 may be collectively referred to as conductive routing. The conductive routing 1603, 1605, 1607, 1609 may be used to route power or signals to, from, or between semiconductor devices 1601 in the device layer 1604 and any external IC devices electrically coupled to the surface contacts 1607.

Although a certain number of internal interconnect layers 1606a-c are shown in the illustrated example, IC device 1600 may include any suitable number of interconnect layers 1606. In some implementations, interconnect layers 1606 that are higher up in the device stack (e.g., further from the device layer 1604) may be thicker than interconnect layers 1606 that are lower in the device stack. In some instances, interconnect layers 1606a-c may be referred to as metal layers or metallization layers. As an example, interconnect layer 1606 a may be referred to as the metal 0 (M0) layer, interconnect layer 1606b may be referred to as the metal 1 (M1) layer, and interconnect layer 1606c may be referred to as the metal 2 (M2) layer.

The dielectric material 1611 in the device layer 1604, the internal interconnect layers 1606, and the external interconnect layer 1608 may vary across the respective layers. Moreover, the conductive features 1603, 1605, 1607, 1609 in IC device 1600 may be formed of any suitable conductive materials (e.g., metal).

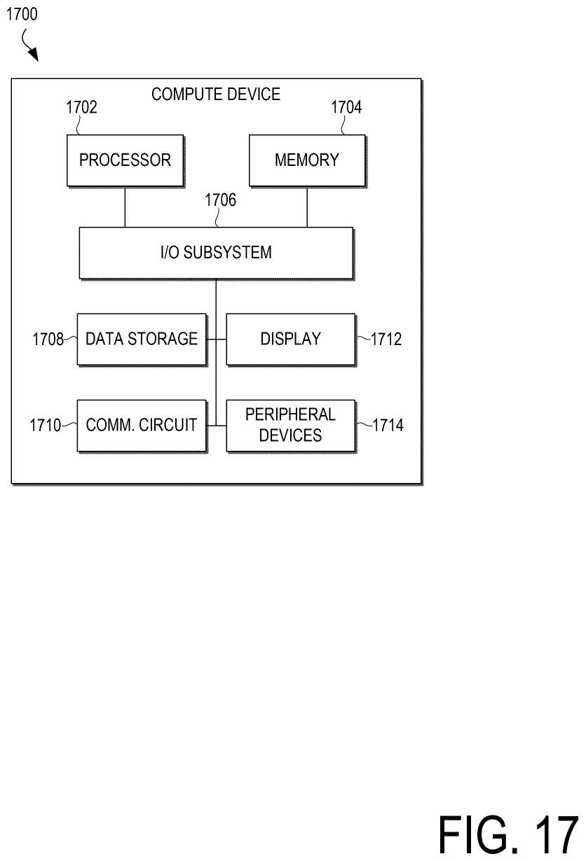

Referring now to FIG. 17, in one example, a block diagram of a compute device 1700 shows various components of the computing device 1700. The compute device 1700 may include any suitable examples of the a high-voltage power silicon carbide transistor 100 disclosed herein. For example, the compute device 1700 or any suitable component thereof may use a high-voltage power silicon carbide transistor 100 as a switch for a high voltage and/or high current signal for various analog or digital circuitry.

The compute device 1700 may be embodied as any type of compute device. For example, the compute device 1700 may be embodied as or otherwise be included in, without limitation, a server computer, an embedded computing system, a System-on-a-Chip (SoC), a multiprocessor system, a processor-based system, a consumer electronic device, a smartphone, a cellular phone, a desktop computer, a tablet computer, a notebook computer, a laptop computer, a network device, a router, a switch, a networked computer, a wearable computer, a handset, a messaging device, a camera device, an application-specific integrated circuit (ASIC), a field-programmable gate array (FPGA), or any other computing device.

The illustrative compute device 1700 includes one or more processors 1702, a memory 1704, an input/output (I/O) subsystem 1706, data storage 1708, a communication circuit 1710, a display 1712, and one or more peripheral devices 1714. In various examples, one or more of the illustrative components of the compute device 1700 may be incorporated in, or otherwise form a portion of, another component. For example, the memory 1704, or portions thereof, may be incorporated in the processor 1702 in various examples. In various examples, one or more of the illustrative components may be physically separated from another component. In some examples, some of the components in the illustrative compute device 1700 may be omitted.

The processor 1702 may be embodied as any type of processor capable of performing the functions described herein. For example, the processor 1702 may be embodied as a single or multi-core processor(s), a single or multi-socket processor, a digital signal processor, a graphics processor, a neural network compute engine, an image processor, a microcontroller, or other processor or processing/controlling circuit. Similarly, the memory 1704 may be embodied as any type of volatile or non-volatile memory or data storage capable of performing the functions described herein. In operation, the memory 1704 may store various data and software used during operation of the compute device 1700 such as operating systems, applications, programs, libraries, and drivers. The memory 1704 is communicatively coupled to the processor 1702 via the I/O subsystem 1706, which may be embodied as circuitry, components, or both to facilitate input/output operations with the processor 1702, the memory 1704, and other components of the compute device 1700. For example, the I/O subsystem 1706 may be embodied as, or otherwise include, memory controller hubs, input/output control hubs, firmware devices, communication links (e.g., without limitation, point-to-point links, bus links, wires, cables, light guides, or printed circuit board traces), other components and subsystems to facilitate the input/output operations. The I/O subsystem 1706 may connect various internal and external components of the compute device 1700 to each other with use of, without limitation, any suitable connector, interconnect, bus, or protocol, such as an SoC fabric, PCIe®, USB2, USB3, USB4, NVMe®, Thunderbolt®, or the like. In various examples, the I/O subsystem 1706 may form a portion of a system-on-a-chip (SoC) and be incorporated, along with the processor 1702, the memory 1704, and other components of the compute device 1700 on a single integrated circuit chip.

The data storage 1708 may be embodied as any type of device or devices configured for the short-term or long-term storage of data. For example, the data storage 1708 may include any one or more memory devices and circuits, memory cards, hard disk drives, solid-state drives, or other data storage devices.

The communication circuit 1710 may be embodied as any type of interface capable of interfacing the compute device 1700 with other compute devices, such as over one or more wired or wireless connections. In various examples, the communication circuit 1710 may be capable of interfacing with any appropriate cable type, such as an electrical cable or an optical cable. The communication circuit 1710 may be configured to use any one or more communication technology and associated protocols (e.g., without limitation, Ethernet, Bluetooth®, Wi-Fi®, WiMAX, or near field communication (NFC)). The communication circuit 1710 may be located on silicon separate from the processor 1702, or the communication circuit 1710 may be included in a multi-chip package with the processor 1702, or even on the same die as the processor 1702. The communication circuit 1710 may be embodied as one or more add-in-boards, daughtercards, network interface cards, controller chips, chipsets, specialized components such as a field-programmable gate array (FPGA) or application-specific integrated circuit (ASIC), or other devices that may be used by the compute device 1700 to connect with another compute device. In various examples, communication circuit 1710 may be embodied as part of a system-on-a-chip (SoC) that includes one or more processors or may be included on a multichip package that also contains one or more processors. In various examples, the communication circuit 1710 may include a local processor (not shown) or a local memory (not shown) or both that are both local to the communication circuit 1710. In such examples, the local processor of the communication circuit 1710 may be capable of performing one or more of the functions of the processor 1702 described herein. Additionally or alternatively, in such examples, the local memory of the communication circuit 1710 may be integrated into one or more components of the compute device 1700 at the board level, socket level, chip level, or other levels.

The display 1712 may be embodied as any type of display on which information may be displayed to a user of the compute device 1700, such as a touchscreen display, a liquid crystal display (LCD), a thin film transistor LCD (TFT-LCD), a light-emitting diode (LED) display, an organic light-emitting diode (OLED) display, a cathode ray tube (CRT) display, a plasma display, an image projector (e.g., 2D or 3D), a laser projector, a heads-up display, or other display technology.

In various examples, the compute device 1700 may include other or additional components, such as those commonly found in a compute device. For example, the compute device 1700 may also have peripheral devices 1714, such as, without limitation, a keyboard, a mouse, or an external storage device. In various examples, the compute device 1700 may be connected to a dock that can interface with various devices, including peripheral devices 1714.

### EXAMPLES

Illustrative examples of the technologies disclosed herein are provided below. An example of the technologies may include any one or more, and any combination of, the examples described below.

Example 1 includes a silicon carbide die comprising a high-voltage power transistor comprising a channel region; a drift region; a gate dielectric stack; and a gate electrode, wherein the gate dielectric stack comprises a first layer and a second layer, wherein the first layer is between the second layer and the channel region, wherein the second layer is between the first layer and the gate electrode, wherein the first layer comprises silicon and oxygen, wherein the second layer comprises nitrogen.

Example 2 includes the subject matter of Example 1, and wherein the second layer comprises silicon and nitrogen.

Example 3 includes the subject matter of any of Examples 1 and 2, and wherein the second layer comprises boron and nitrogen.

Example 4 includes the subject matter of any of Examples 1-3, and wherein the first layer comprises silicon oxide, wherein the second layer comprises silicon nitride.

Example 5 includes the subject matter of any of Examples 1-4, and wherein the second layer of the gate dielectric stack impacts a stress between the first layer of the gate dielectric stack and the channel region.

Example 6 includes the subject matter of any of Examples 1-5, and wherein the impact to the stress between the first layer of the gate dielectric stack and the channel region improves an electron mobility in the channel region.

Example 7 includes the subject matter of any of Examples 1-6, and wherein an electron mobility in the channel region is at least 40 square centimeters per Volt-second.

Example 8 includes the subject matter of any of Examples 1-7, and wherein the first layer has a thickness of at least 40 nanometers, wherein the second layer has a thickness less than 20 nanometers.

Example 9 includes an apparatus comprising a die comprising silicon and carbon; a channel region defined in the die; a gate dielectric stack adjacent a top surface of the die; and a gate electrode adjacent the gate dielectric stack, wherein the gate dielectric stack comprises a first layer and a second layer, wherein the first layer is between the second layer and the channel region, wherein the second layer is between the first layer and the gate electrode, wherein the first layer comprises silicon and oxygen, wherein the second layer comprises nitrogen.

Example 10 includes the subject matter of Example 9, and wherein the second layer comprises silicon and nitrogen.

Example 11 includes the subject matter of any of Examples 9 and 10, and wherein the second layer comprises boron and nitrogen.

Example 12 includes the subject matter of any of Examples 9-11, and wherein the first layer comprises silicon oxide, wherein the second layer comprises silicon nitride.

Example 13 includes the subject matter of any of Examples 9-12, and wherein the second layer of the gate dielectric stack impacts a stress between the first layer of the gate dielectric stack and the channel region.

Example 14 includes the subject matter of any of Examples 9-13, and wherein the impact to the stress between the first layer of the gate dielectric stack and the channel region improves an electron mobility in the channel region.

Example 15 includes a method comprising epitaxially growing a drift region on a silicon carbide die; creating one or more wells in the drift region; growing an oxide layer above at least part of the one or more wells, the oxide layer adjacent the one or more wells; growing a nitride layer above the oxide layer, the nitride layer adjacent the oxide layer; and forming a gate electrode on the nitride layer.

Example 16 includes the subject matter of Example 15, and wherein the nitride layer comprises silicon and nitrogen.

Example 17 includes the subject matter of any of Examples 15 and 16, and wherein the nitride layer comprises boron and nitrogen.

Example 18 includes the subject matter of any of Examples 15-17, and wherein the oxide layer comprises silicon and oxygen.

Example 19 includes the subject matter of any of Examples 15-18, and wherein the nitride layer impacts a stress between the oxide layer and the one or more wells.

Example 20 includes the subject matter of any of Examples 15-19, and wherein the impact to the stress between the nitride layer and the oxide layer improves an electron mobility in a channel region of the one or more wells.

Example 21 includes the subject matter of any of Examples 15-20, and further including; defining a photoresist layer on the nitride layer; etching the oxide layer not protected by the photoresist layer; and etching the nitride layer not protected by the photoresist layer.

1. A silicon carbide die comprising:
a high-voltage power transistor comprising:
a channel region;
a drift region;
a gate dielectric stack; and
a gate electrode,
wherein the gate dielectric stack comprises a first layer and a second layer, wherein the first layer is between the second layer and the channel region, wherein the second layer is between the first layer and the gate electrode,
wherein the first layer comprises silicon and oxygen,
wherein the second layer comprises nitrogen.

2. The silicon carbide die of claim 1, wherein the second layer comprises silicon and nitrogen.

3. The silicon carbide die of claim 1, wherein the second layer comprises boron and nitrogen.

4. The silicon carbide die of claim 1, wherein the first layer comprises silicon oxide, wherein the second layer comprises silicon nitride.

5. The silicon carbide die of claim 1, wherein the second layer of the gate dielectric stack impacts a stress between the first layer of the gate dielectric stack and the channel region.

6. The silicon carbide die of claim 5, wherein an impact to the stress between the first layer of the gate dielectric stack and the channel region improves an electron mobility in the channel region.

7. The silicon carbide die of claim 1, wherein an electron mobility in the channel region is at least 40 square centimeters per Volt-second.

8. The silicon carbide die of claim 1, wherein the first layer has a thickness of at least 40 nanometers, wherein the second layer has a thickness less than 20 nanometers.

9. An apparatus comprising:
a die comprising silicon and carbon;
a channel region defined in the die;
a gate dielectric stack adjacent a top surface of the die; and
a gate electrode adjacent the gate dielectric stack,
wherein the gate dielectric stack comprises a first layer and a second layer, wherein the first layer is between the second layer and the channel region, wherein the second layer is between the first layer and the gate electrode,
wherein the first layer comprises silicon and oxygen,
wherein the second layer comprises nitrogen.

10. The apparatus of claim 9, wherein the second layer comprises silicon and nitrogen.

11. The apparatus of claim 9, wherein the second layer comprises boron and nitrogen.

12. The apparatus of claim 9, wherein the first layer comprises silicon oxide, wherein the second layer comprises silicon nitride.

13. The apparatus of claim 9, wherein the second layer of the gate dielectric stack impacts a stress between the first layer of the gate dielectric stack and the channel region.

14. The apparatus of claim 13, wherein an impact to the stress between the first layer of the gate dielectric stack and the channel region improves an electron mobility in the channel region.

15. A method comprising:
epitaxially growing a drift region on a silicon carbide die;
creating one or more wells in the drift region;
growing an oxide layer above at least part of the one or more wells, the oxide layer adjacent the one or more wells;
growing a nitride layer above the oxide layer, the nitride layer adjacent the oxide layer; and
forming a gate electrode on the nitride layer.

16. The method of claim 15, wherein the nitride layer comprises silicon and nitrogen.

17. The method of claim 15, wherein the nitride layer comprises boron and nitrogen.

18. The method of claim 15, wherein the oxide layer comprises silicon and oxygen.

19. The method of claim 15, wherein the nitride layer impacts a stress between the oxide layer and the one or more wells.

20. The method of claim 15, further comprising;
defining a photoresist layer on the nitride layer;
etching the oxide layer not protected by the photoresist layer; and
etching the nitride layer not protected by the photoresist layer.
